(19) United States
(12) Patent Application Publication
(10) Pub. No.: US 2025/0255096 A1
(43) Pub. Date: Aug. 7, 2025

(54) LIGHT EMITTING DEVICE AND LIGHT EMITTING DISPLAY DEVICE

(71) Applicant: LG Display Co., Ltd., Seoul (KR)

(72) Inventor: Mi Young HAN, Paju-si (KR)

(73) Assignee: LG Display Co., Ltd., Seoul (KR)

(21) Appl. No.: 18/788,334

(22) Filed: Jul. 30, 2024

(30) Foreign Application Priority Data
Feb. 7, 2024 (KR) 10-2024-0019169

(51) Int. Cl. H10K 50/17

(52) U.S. Cl. CPC H10K 50/171

(57) ABSTRACT

Disclosed are a light emitting device and a light emitting display device, the light emitting device including a first electrode and a second electrode facing each other, at least one stack of layers between the first electrode and the second electrode and including a hole transport layer, an emission layer, and an electron transport layer, and an electron injection unit provided between the at least one stack and the second electrode and including a first n-type layer, a p-type layer, and a second n-type layer.

This application claims the benefit of Korean Patent Application No. 10-2024-0019169, filed on Feb. 7, 2024, which is hereby incorporated by reference as if fully set forth herein.

### TECHNICAL FIELD

The present disclosure relates to a light emitting device with improved efficiency and luminance by changing the structure of the light emitting device and a light emitting display device using the same.

### BACKGROUND

With the advent of the information era, the display field that visually displays electrical information signals has developed rapidly, and accordingly, a variety of display devices with excellent performance such as slimness, light weight, and low power consumption are being developed.

A light emitting display device is configured such that there is no need for a separate light source and a light emitting device is provided in a display panel for compactness of the device and clear color display is being considered as a competitive application.

A light emitting device may include an anode and a cathode facing each other as electrodes, an emission layer between the anode and the cathode, and a common layer that transfers holes and electrons to the emission layer.

Also, a light emitting device is configured to include a dielectric with a light emitting function between two electrodes, and a barrier for carrier injection is large due to interfacial resistance with the electrodes, which leads to a decrease in efficiency.

### SUMMARY

A light emitting device and a light emitting display device are disclosed. The light emitting device can improve electron injection characteristics and increase the amount of electrons injected by changing the configuration of an electron injection unit in contact with the second electrode (anode), which can improve efficiency of an emission layer.

A light emitting device and a light emitting display device can improve color purity of the emission layer of a stack adjacent to the electron injection unit due to increased electron injection when the configuration of the electron injection unit is changed.

A light emitting device and a light emitting display device are disclosed having a configuration to prevent operating voltage deterioration and improve efficiency and lifespan.

An aspect of the present disclosure provides a light emitting device, including a first electrode and a second electrode facing each other, at least one stack provided between the first electrode and the second electrode and including a hole transport layer, an emission layer, and an electron transport layer, and an electron injection unit provided between the at least one stack and the second electrode and including a first n-type layer, a p-type layer, and a second n-type layer.

Another aspect of the present disclosure provides a light emitting display device, including a substrate including a plurality of sub-pixels and a thin film transistor provided in each of the plurality of sub-pixels, in which at least one of the sub-pixels may include the light emitting device described above and the first electrode of the light emitting device may be connected to the thin film transistor.

### BRIEF DESCRIPTION OF THE DRAWINGS

The accompanying drawings, which are included to provide a further understanding of the disclosure and are incorporated in and constitute a part of this application, illustrate aspect(s) of the disclosure and together with the description serve to explain the principle of the disclosure. In the drawings:

FIG. 1 is a cross-sectional view showing a light emitting device according to an aspect of the present disclosure;

FIG. 2 shows energy band diagrams of a second electrode, an electron injection unit adjacent to the second electrode, and an electron transport layer of the light emitting device according to an aspect of the present disclosure;

FIGS. 3 to 5 are cross-sectional views showing light emitting devices according to various aspects of the present disclosure;

FIG. 6 is a graph showing spectra of light emitting devices of first and second examples;

FIG. 7 is a graph showing normalized spectra of light emitting devices of the first and second examples;

FIG. 8 is a graph showing lifespan of the light emitting devices of the first and second examples;

FIG. 9 is a graph showing spectra of light emitting devices of first, third, and fourth examples;

FIG. 10 is a graph showing normalized spectra of light emitting devices of the first, third, and fourth examples;

FIG. 11 is a graph showing lifespan of light emitting devices of the first, third, and fourth examples;

FIG. 12 is a graph showing current density characteristics of light emitting devices of the first, fifth, and sixth examples;

FIG. 13 is a graph showing relationships between current density and luminance of light emitting devices of the first, fifth, and sixth examples;

FIG. 14 is a graph showing spectra of the light emitting devices of the first, fifth, and sixth examples;

FIG. 15 is a graph showing lifespan of light emitting devices of the first, fifth, and sixth examples;

FIG. 16 is a graph showing current density characteristics of light emitting devices of seventh and eighth examples;

FIG. 17 is a graph showing spectra of light emitting devices of the seventh and eighth examples;

FIG. 18 is a graph showing lifespan of light emitting devices of the seventh and eighth examples; and

FIG. 19 is a cross-sectional view showing a display device according to an aspect of the present disclosure.

### DETAILED DESCRIPTION

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations may unnecessarily obscure an important point of the present disclosure, a detailed description of such steps, elements, functions, technologies, and configurations maybe omitted. In addition, the names of elements used in the following description are selected in consideration of clarity of description of the specification, and may differ from the names of elements of actual products. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components may be added, unless the term, such as “only,” is used. As used herein, the term “and/or” includes a single associated listed item and any and all of the combinations of two or more of the associated listed items.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element may be present between the two elements, unless “immediate(ly)” or “direct(ly)” or “close(ly) is used. It will be understood that when an element or layer is referred to as being “connected to”, or “coupled to” another element or layer, it may be directly connected to or coupled to the other element or layer, or one or more intervening elements or layers may be present.

In describing the various example embodiments of the present disclosure, when terms such as “after,” “subsequently,” “next,” and “before,” are used to describe the temporal relationship between two events, another event may occur therebetween, unless a more limiting term, such as “just,” “immediate(ly),” or “directly” is used.

In describing the various example embodiments of the present disclosure, terms such as “first” and “second” may be used to describe a variety of components. These terms aim to distinguish the same or similar components from one another and do not limit the components. Accordingly, throughout the specification, a “first” component may be the same as a “second” component within the technical concept of the present disclosure, unless specifically mentioned otherwise.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other or may be carried out together in a co-dependent relationship.

In the following description of the present disclosure, the Lowest Unoccupied Molecular Orbital (LUMO) level and the Highest Occupied Molecular Orbital (HOMO) level of a layer mean the LUMO level and the HOMO level of a material constituting a major weight ratio of the corresponding layer, unless they refer to the LUMO level and the HOMO level of a dopant material doping the corresponding layer.

In the following description of the present disclosure, a HOMO level may be an energy level measured through cyclic voltammetry (CV), in which an energy level is determined from a relative potential value to a reference electrode having a known potential value. For example, the HOMO level of a material may be measured using NPD having known oxidation potential value and reduction potential value.

As used herein, the term “doped” layer refers to a layer including a first material and a second material (for example, n-type and p-type materials, or organic and inorganic substances) having physical properties different from the first material. Apart from the differences in properties, the first and second materials may also differ in terms of their amounts in the doped layer. For example, the host material may be a major component while the dopant material may be a minor component. The first material accounts for most of the weight of the doped layer. The second material may be added in an amount less than 30% by weight, based on a total weight of the first material in the doped layer. A “doped” layer may be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Also, the term “undoped” refers to layers that are not “doped”. For example, a layer may be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum may be calculated by multiplying (a) a photoluminescence (PL) spectrum, which applies the inherent characteristics of an emissive material such as a dopant material or a host material included in an organic emission layer, by (b) an out-coupling or emittance spectrum curve, which is determined by the structure and optical characteristics of an organic light-emitting element including the thicknesses of organic layers such as, for example, an electron transport layer.

Hereinafter, example aspects of the present disclosure will be described in detail with reference to the accompanying drawings. In adding reference numerals to elements of each of the drawings, although the same elements are illustrated in other drawings, like reference numerals may refer to like elements. Also, for convenience of description, a scale in which each of elements is illustrated in the accompanying drawings may differ from an actual scale. Thus, the illustrated elements are not limited to the specific scale in which they are illustrated in the drawings.

Hereinafter, a detailed description will be given of a light emitting device and a light emitting display device according to the present disclosure with reference to the accompanying drawings.

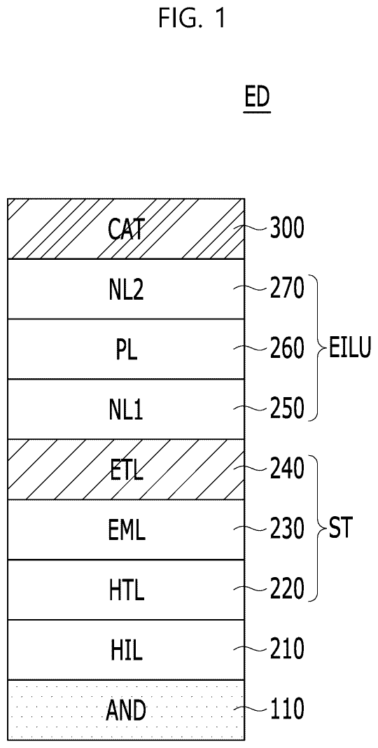

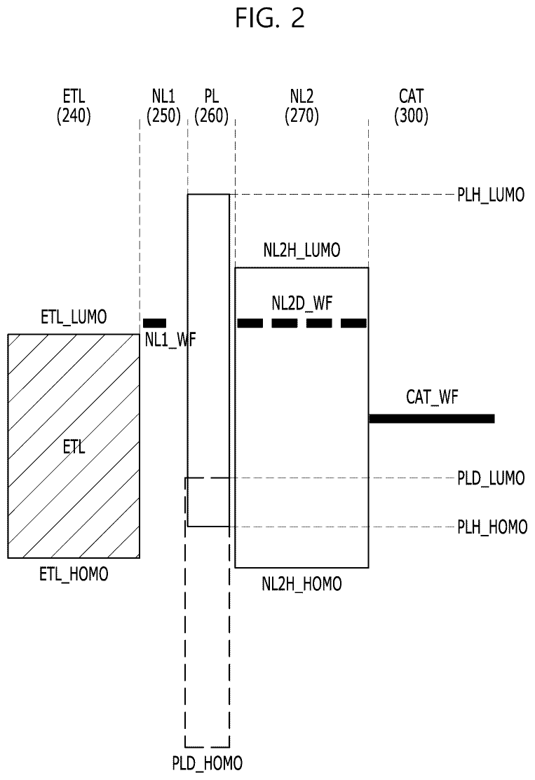

FIG. 1 is a cross-sectional view showing a light emitting device according to an aspect of the present disclosure. FIG. 2 shows energy band diagrams of a second electrode, an electron injection unit EILU adjacent to the second electrode, and an electron transport layer of the light emitting device according to an aspect of the present disclosure.

As shown in FIG. 1, the light emitting device according to an aspect of the present disclosure may include a first electrode 110 and a second electrode 300 facing each other, and a hole injection layer 210, a hole transport layer 220, an emission layer 230, an electron transport layer 240, and an electron injection unit EILU, which are sequentially provided between the first electrode 110 and the second electrode 300.

Any one of the first electrode 110 and the second electrode 300 may be an anode and the remaining one may be a cathode. Any one of the first electrode 110 and the second electrode 300 may be a reflective electrode, and the remaining one may be a transparent electrode or a semi-transparent electrode.

The first electrode 110 may be connected to a thin film transistor provided on a substrate to selectively receive a signal supplied to each sub-pixel, and the second electrode 300 may be provided in common to sub-pixels to receive a common voltage.

The hole injection layer 210 may be made of a single organic or inorganic hole injection material, or may be formed by adding a p-type dopant to a hole transport material. The hole injection layer 210 reduces a barrier in supplying holes from the first electrode 110 to an intermediate layer structure 200.

For example, the hole transport layer 220 may be formed of an amine-based hole transport material. Holes injected through the hole injection layer 210 are transferred toward the emission layer 250.

In some cases, the organic material included in the hole injection layer 210 and the organic material included in the hole transport layer 220 may be the same component.

The emission layer 230 may be made of an emission material that varies depending on the emission color desired to be displayed by the light emitting device ED. The emission layer 230 may include at least one host and at least one dopant. The emission layer 230 may have a monolayer or multilayer structure as necessary. When the emission layer 230 is provided as a plurality of layers, at least one of the host or the dopant may be different in adjacent layers.

The emission layer 230 may include any one selected from among a red emission layer, a green emission layer, and a blue emission layer. In some cases, the emission layer may further include a white emission layer. Alternatively, the emission layer 230 may be composed of emission layers of other colors that may appear white when combined, rather than emission layers of three primary colors of red/green/blue. For example, arrangement of cyan, magenta, and yellow emission layers is also possible.

The electron transport layer 240 may be formed of, for example, an anthracene-based electron transport material. The electron transport layer 240 may transfer electrons from the electron injection unit EILU toward the emission layer 230.

In the light emitting device according to an aspect of the present disclosure, when an electric field is generated by a voltage difference between the first electrode 110 and the second electrode 300, holes transferred by the hole injection layer 210 and the hole transport layer 220 and electrons transferred by the electron injection unit EILU and the electron transport layer 240 recombine in the emission layer 230 to form excitons, and the energy level of the excitons thus formed decreases to a ground state, emitting light.

The electron injection unit EILU of the light emitting device according to an aspect of the present disclosure may include a first n-type layer NL1 250, a p-type layer PL 260, and a second n-type layer NL2 270.

The first n-type layer NL1 250, the p-type layer PL 260, and the second n-type layer NL2 270 are continuously arranged, and the first n-type layer 250 is in contact with the p-type layer 260 and the p-type layer 260 is in contact with the second n-type layer 270.

In the electron injection unit EILU, the first n-type layer 250, the p-type layer 260, and the second n-type layer 270 all may include an organic material as a main material. Some layers may include an alkali metal with a low work function that is advantageous for electron injection.

Specifically, the first n-type layer 250 may be made of an n-type organic material or an n-type inorganic material, which may include any material selected from the group consisting of lithium fluoride (LiF), lithium oxide (Li₂O), Li-containing organometallic compounds, Cs-containing organometallic compounds, cesium fluoride (CsF), cesium oxide (Cs₂O), cesium carbonate (Cs₂CO₃), and combinations thereof. The organometallic compound coupled with lithium (Li) or cesium (Cs) may be an alkyl metal compound or an aryl metal compound. Examples thereof may include, but are not limited to, phenyllithium, t-butyllithium, and methylcesium. In some embodiments, the first n-type layer 250 is made of LiF.

The p-type layer 260 is made of an organic material with strong electron acceptor characteristics. The p-type layer 260 may include an organic material with electron acceptor characteristics alone or may include a p-type host PLH with electron acceptor characteristics and a p-type dopant PLD with a lower energy band gap than the p-type host.

The p-type host of the p-type layer 260 may include an organic material including at least one selected from among, for example, NPD, HAT-CN, TPD, TNB, TCTA, N,N′-dioctyl-3,4,9,10-perylenedicarboximide (PTCDI-C8), and indacene derivatives.

Examples of the dopant PLD of the p-type layer 260 may include materials such as F4TCNQ, radialene, and the like.

The second n-type layer 270 may include an organic material with strong electron donor characteristics. For example, the second n-type layer 270 may include an n-type host NL2H and an n-type dopant NL2D.

The organic material with strong electron donor characteristics included in the second n-type layer 270 may include, for example, a phenanthroline-based compound of Chemical Formula 1 below.

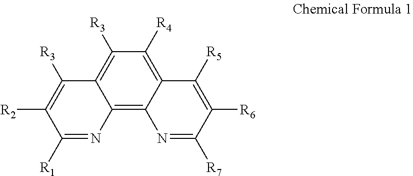

In chemical formula 1, R₁ to R₈ may be independently selected from among hydrogen, deuterium, halogen, cyano (CN) group, C1-C20 alkyl, C3-C20 cycloalkyl, substituted or unsubstituted C6-C30 aryl, and substituted or unsubstituted C5-C30 heteroaryl.

Examples of the n-type host NL2H of the second n-type layer 270 may include bismuth copper oxide (BCP), BPhen, and 2-phenanthroline.

Here, the n-type dopant NL2D of the second n-type layer 270 may include an alkali metal such as lithium (Li) or Cs, or a lanthanide metal such as ytterbium (Yb), etc. The n-type dopant NL2D may be contained in a small amount of less than 2 vol % in the second n-type layer 270.

In the second n-type layer 270, the n-type host NL2H may be filled with electrons by the n-type dopant NL2D, a new gap state may be created, and the Fermi level may approach the LUMO energy level of the n-type host NL2H.

The second n-type layer 270 including an n-type host NL2H and an n-type dopant NL2D and the p-type layer 260 including a p-type host PLH and a p-type dopant PLD are illustrated in FIG. 2.

As for the material of the second n-type layer 270, the n-type host NL2H is made of an organic material with a HOMO energy level of −6.1 eV and a LUMO energy level of −2.7 eV, and the n-type dopant NL2D includes lithium (Li) ions.

Both the p-type host PLH and the p-type dopant PLD of the p-type layer 260 are made of organic materials. The p-type host PLH is made of an organic material with a HOMO energy level of −5.5 eV and a LUMO energy level of −2.4 eV, and the p-type dopant PLD is made of an organic material with a HOMO energy level of −7.4 eV and a LUMO energy level of −5.1 eV.

As shown in FIG. 2, the first n-type layer 250 is made of a compound containing LiF as a single n-type inorganic material.

The second electrode CAT 300 is made of aluminum with a work function of 4.3 eV.

The electron transport layer 240 is configured such that the absolute value of the LUMO energy level thereof is not significantly different from the work function of the first n-type layer 250 so that the energy barrier is not large when electrons are injected through the adjacent first n-type layer 250. As shown in FIG. 2, the electron transport layer 240 is made of an organic material with a HOMO energy level of −6.0 eV and a LUMO energy level of −3.0 eV.

Here, when each of the n-type dopant NL2D of the second n-type layer 270 and the n-type inorganic material of the first n-type layer 250 contains a metal, electrons may move depending on the work function of the metal.

Therefore, when a bias voltage is applied to the second electrode CAT 300 and electrons are injected into the second n-type layer 270 through the second electrode CAT 300, upon filling of the n-type host NL2H of the second n-type layer 270 with electrons, electrons may move depending on the work function of the n-type dopant NL2D adjacent to the LUMO energy level of the n-type host NL2H, and electrons may pass through the p-type layer 260 between the second n-type layer 270 and the first n-type layer 250 by a tunneling effect, may move depending on the work function of lithium in the first n-type layer 250, and may be transferred to the LUMO energy level of the adjacent electron transport layer 240.

The second electrode CAT 300 and the second n-type layer 270 may be in direct contact with each other, and the first n-type layer 250 may be in direct contact with the electron transport layer 240.

In the light emitting device according to an aspect of the present disclosure, the electron injection unit EILU serves to increase electron injection efficiency and the efficiency of the light emitting device.

Compared to the structure of the electron injection unit according to an aspect of the present disclosure, when the thickness of a single electron injection layer is increased or a plurality of the same n-type layers having electron injection characteristics is provided, interfacial resistance may increase and operating voltage may rise. Moreover, in the present disclosure, it is confirmed that, when a plurality of the same n-type layers having electron injection characteristics is provided, efficiency is not greatly improved compared to when forming a single n-type layer. Accordingly, the light emitting device according to an aspect of the present disclosure includes different types of layers that are alternately provided at the interface with the second electrode CAT 300 configured to inject electrons.

In the electron injection unit EILU, the first n-type layer 250 is in contact with the electron transport layer 240 and transfers electrons to the emission layer 230 through the electron transport layer 240 by the flow of current generated when the second electrode CAT 300 is biased.

The electron injection unit EILU according to an aspect of the present disclosure further includes, in addition to the first n-type layer 250 that primarily functions to inject electrons, the p-type layer 260 and the second n-type layer 270 provided between the first n-type layer 250 and the second electrode CAT 300, and a pn junction is generated between the p-type layer 260 and the second n-type layer 270.

The p-type layer 260 and the second n-type layer 270, having different polarities, generate holes and electrons, respectively, due to a difference in polarity therebetween. When a bias voltage is applied to the second electrode CAT 300, a strong flow of electrons is generated from the second electrode CAT 300 toward the emission layer 230, and electrons generated in the second n-type layer 270 pass through the p-type layer 260 by a tunneling effect without any barrier by the band gap of the p-type layer 260 and move to the first n-type layer 250, and electrons are transferred in an increased amount from the first n-type layer 250 to the electron transport layer 240. Briefly, the first and second n-type layers 250, 270 multiply the generation of electrons to transfer the electrons toward the electron transport layer 240, and ultimately, formation of excitons may be improved in the emission layer 230, increasing luminous efficacy.

Here, holes generated in the p-type layer 260 may be emitted toward the second electrode CAT 300 in the opposite direction to the electrons.

In the electron injection unit EILU, the first n-type layer 250 has a thickness of 10 Å to 30 Å. In the electron injection unit EILU, the first n-type layer 250 may be the thinnest. This is because the p-type layer 260 and the second n-type layer 270 in the light emitting device ED contain an organic material, preventing an increase in resistance when the inorganic material of the first n-type layer 250 is disposed apart from the second electrode CAT 300 and obtaining optimal electron injection efficiency.

The p-type layer 260 may have a thickness of 20 Å to 50 Å, and the second n-type layer 270 may have a thickness of 20 Å to 100 Å. The p-type layer 260 and the second n-type layer 270 are made of organic materials and are formed to thicknesses of 20 Å or more suitable for ensuring deposition reproducibility. To improve electron injection efficiency and prevent an increase in operating voltage, the upper limits of the thicknesses thereof are set to 50 Å and 100 Å, respectively.

The p-type layer 260 may be thinner than the second n-type layer 270 for a tunneling effect.

In FIG. 1, the stacked structure of the hole transport layer HTL 220, the emission layer EML 230, and the electron transport layer ETL 240 may function as a single stack ST. For example, the light emitting device ED may include a single stack ST between the first electrode 110 and the second electrode 300, as shown in FIG. 1, or may include multiple stacks ST between the first electrode 110 and the second electrode 300. An example in which multiple stacks are provided between the first electrode 110 and the second electrode 300 will be described later.

The hole injection layer 210 of FIG. 1 is configured to be in contact with the first electrode 110, and the electron injection unit EILU is configured to be in contact with the second electrode 300. In a structure with multiple stacks, the hole injection layer 210 may be provided only in the stack adjacent to the first electrode 110, and the electron injection unit EILU may be provided only in the stack adjacent to the second electrode 300.

A charge generation layer may be provided between stacks ST, and holes and electrons for each stack may be supplied through the adjacent charge generation layer.

Below is a description of a light emitting device with multiple stacks.

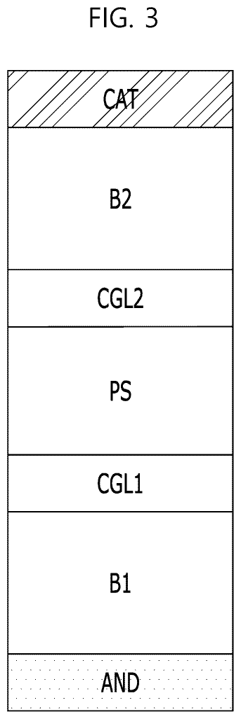

FIGS. 3 to 5 are cross-sectional views showing light emitting devices according to various aspects of the present disclosure.

As shown in FIG. 3, the light emitting device according to an aspect of the present disclosure may include multiple stacks B1, PS, B2 between the first electrode AND (e.g., an anode) and the second electrode CAT (e.g., a cathode).

Charge generation layers CGL1, CGL2 are provided between the stacks B1, PS, B2.

Each of the charge generation layers CGL1, CGL2 may include an n-type charge generation layer and a p-type charge generation layer.

Each of the stacks B1, PS, B2 may include a hole transport layer, an emission layer, and an electron transport layer, and holes or electrons may be applied to the electrodes AND, CAT or the charge generation layers CGL1, CGL2 adjacent to each stack. Excitons may be generated for each stack, thus improving efficiency in multiple stacks compared to a single stack.

The emission layer included in the first blue stack B1 and the second blue stack B2 is a blue emission layer that emits blue light, and may include, for example, at least one blue host and at least one blue dopant. In addition, the first and second blue stacks B1, B2 that emit blue light may further include an electron blocking layer between the hole transport layer and the emission layer to control the flow of electrons and excitons from the blue emission layer toward the hole transport layer. Briefly, each of the first and second blue stacks B1, B2 may include a hole transport layer, an electron blocking layer, a blue emission layer, and an electron transport layer.

A phosphorescent stack PS including a phosphorescent emission layer is provided between the first and second blue stacks B1, B2. In order for the light emitting device of FIG. 3 to emit white light, the phosphorescent stack PS may further include a phosphorescent emission layer with a longer wavelength than blue.

For example, the phosphorescent emission layer of the phosphorescent stack PS may include a yellow-green emission layer or a green emission layer alone. According to another aspect, the phosphorescent emission layer of the phosphorescent stack PS may sequentially include a red emission layer and a green emission layer. According to still another aspect, the phosphorescent emission layer of the phosphorescent stack PS may sequentially include a red emission layer, a yellow-green emission layer, and a green emission layer. In some cases, there may be provided a plurality of emission layers, in which at least one selected from among a red emission layer, a yellow-green emission layer, and a green emission layer may emit light of the same color but the ratio of hosts may be differently set or the dopants may be used in different amounts.

For example, the phosphorescent stack PS may include a hole transport layer, a red emission layer, a yellow-green emission layer, a first green emission layer, a second green emission layer, and an electron transport layer, which are sequentially formed. In some cases, when the phosphorescent stack PS includes a plurality of phosphorescent emission layers, the phosphorescent emission layer adjacent to the lower charge generation layer among the phosphorescent emission layers may contribute to hole transport, and the phosphorescent emission layer adjacent to the upper charge generation layer may contribute to electron transport. In some cases, the hole transport layer or the electron transport layer may be omitted in the phosphorescent stack PS.

Although FIG. 3 shows the phosphorescent stack PS disposed between the first and second blue stacks B1, B2, the light emitting device of the present disclosure is not limited thereto. The phosphorescent stack PS may be formed adjacent to either the first electrode AND or the second electrode CAT. In some cases, to improve color purity, the phosphorescent stack PS may be divided by color and may be dividedly formed between the first electrode AND and the second electrode CAT.

Also, in the light emitting device according to an aspect of the present disclosure, the first blue stack B1 adjacent to the first electrode AND among the stacks B1, PS, B2 provided in FIG. 3 may further include a hole injection layer, and the second blue stack B2 adjacent to the second electrode CAT may further include the electron injection unit EILU shown in FIG. 1.

When the stack adjacent to the second electrode CAT is a phosphorescent stack, an electron injection unit EILU may be provided between the electron transport layer of the phosphorescent stack and the second electrode CAT.

Although three stacks are illustrated in the drawing, the light emitting device according to an aspect of the present disclosure may be configured to include a single blue stack and a single phosphorescent stack between the first electrode and the second electrode with a charge generation layer interposed therebetween. As such, it may include the electron injection unit having a multilayer structure as shown in FIG. 1 in contact with the second electrode.

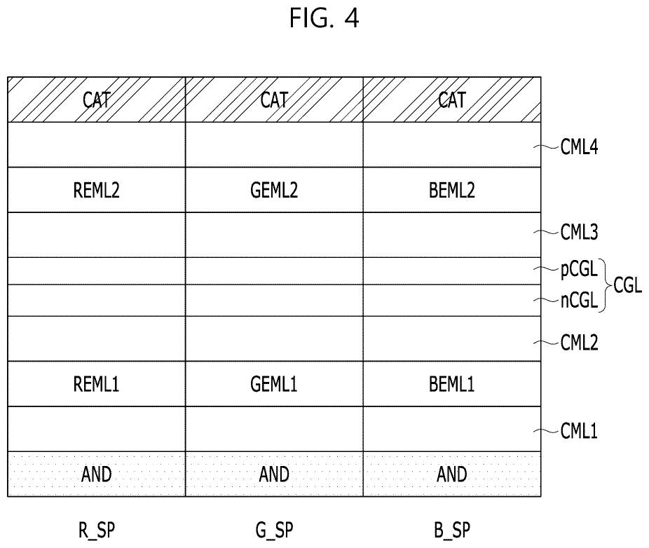

As shown in FIG. 4, the light emitting device according to an aspect of the present disclosure includes a first electrode AND and a second electrode CAT facing each other provided to each of a red sub-pixel R_SP, a green sub-pixel G_SP, and a blue sub-pixel B_SP, and multiple stacks between the first electrode AND and the second electrode CAT, in which the stacks have emission layers that emit light of the same color overlapping with each other. Specifically, the red sub-pixel R_SP may include red emission layers REML1, REML2 in separate stacks with a charge generation layer CGL interposed therebetween, the green sub-pixel G_SP may include green emission layers GEML1, GEML2 in separate stacks with a charge generation layer CGL interposed therebetween, and the blue sub-pixel B_SP may include blue emission layers BEML1, GEML2 in separate stacks with a charge generation layer CGL interposed therebetween.

Here, a first common layer CML1 related to hole injection and hole transport is provided between the first electrode AND and the first red emission layer REML1, the first green emission layer GEML1, and the first blue emission layer BEML1, and a second common layer CML2 related to electron transport is provided between the first red emission layer REML1, the first green emission layer GEML1, and the first blue emission layer BEML1 and the charge generation layer CGL.

The charge generation layer CGL may be provided by stacking an n-type charge generation layer nCGL and a p-type charge generation layer pCGL.

In addition, a third common layer CML3 related to hole injection and hole transport may be provided between the charge generation layer CGL and the second red emission layer REML2, the second green emission layer GEML2, and the second blue emission layer BEML2, and a fourth common layer CML4 including an electron transport layer and an electron injection layer may be provided between the second red emission layer REML2, the second green emission layer GEML2, and the second blue emission layer BEML2 and the second electrode CAT.

The first common layer CML1 and the third common layer CML3 may include at least one selected from among a hole injection layer, a hole transport layer, and an electron blocking layer, and the second common layer CML2 and the fourth common layer CML4 may include at least one selected from among a hole blocking layer, an electron transport layer, and an electron injection layer.

Here, the fourth common layer CML4 in contact with the second electrode CAT may include the configuration of an electron transport layer and an electron injection unit, as shown in FIG. 1 or 2. Here, the electron injection unit is configured to include a first n-type layer, a p-type layer, and a second n-type layer, in which the p-type layer and the second n-type layer of a pn junction mainly composed of organic materials in contact with the second electrode CAT are further provided, in addition to the first n-type layer 250 having electron injection characteristics.

In another aspect of the present disclosure, a configuration in which two or more blue stacks and two or more phosphorescent stacks are included between the first electrode and the second electrode is also possible.

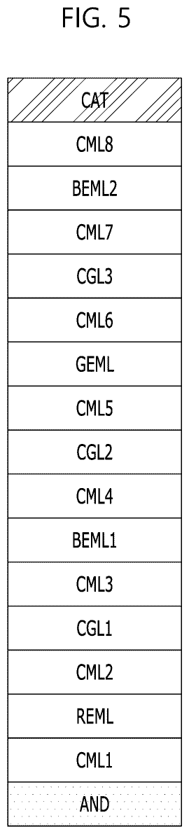

As shown in FIG. 5, the light emitting device according to an aspect of the present disclosure may include at least four stacks divided by charge generation layers CGL1, CGL2, CGL3 between the first electrode AND and the second electrode CAT.

Each stack may include an emission layer REML, BEML1, GEML, BEML2 at the center, and may include a hole transport-related common layer CML1, CML3, CML5, CML7 under the emission layer REML, BEML1, GEML, BEML2, and an electron transport-related common layer CML2, CML4, CML6, CML8 thereon.

As described above, the eighth common layer CML8 in contact with the second electrode CAT may include the configuration of an electron transport layer and an electron injection unit, as shown in FIG. 1 or 2. Here, the electron injection unit is configured to include a first n-type layer 250, a p-type layer 260, and a second n-type layer 270, in which the p-type layer 260 and the second n-type layer 270 of a pn junction mainly composed of organic materials in contact with the second electrode CAT are further provided, in addition to the first n-type layer 250 having electron injection characteristics.

The arrangement of four stacks is illustrated in FIG. 5, and the position of the first blue emission layer BEML1 may be changed to another stack.

Also, the efficiency of the light emitting device may be further improved by including an additional stack in addition to the three stacks or four stacks described above.

Below, significance of the electron injection unit of the light emitting device according to an aspect of the present disclosure is examined through experiments.

The device used in the following experiments has the structure of FIG. 1, including a green emission layer as an emission layer. In the following experiments, individual examples are different in the configuration of the electron injection unit EILU.

### First Experiment

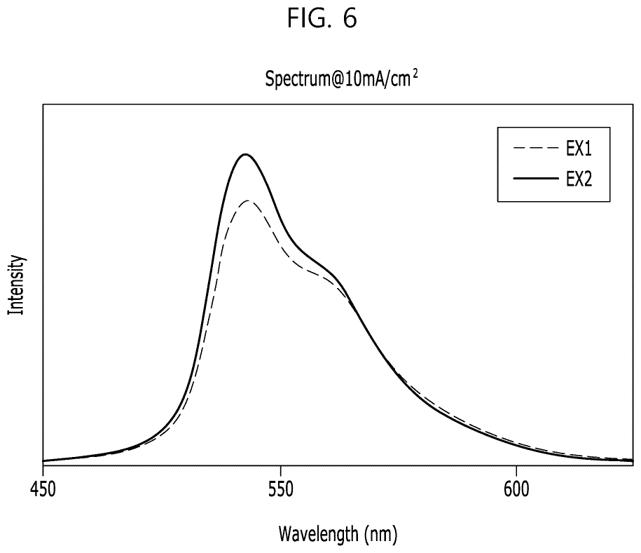

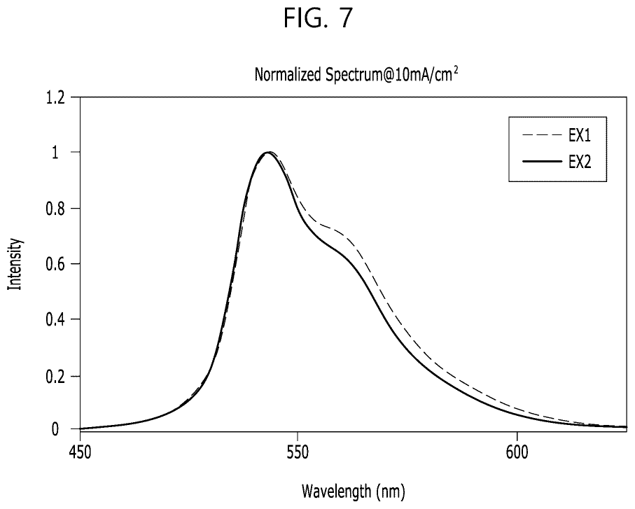

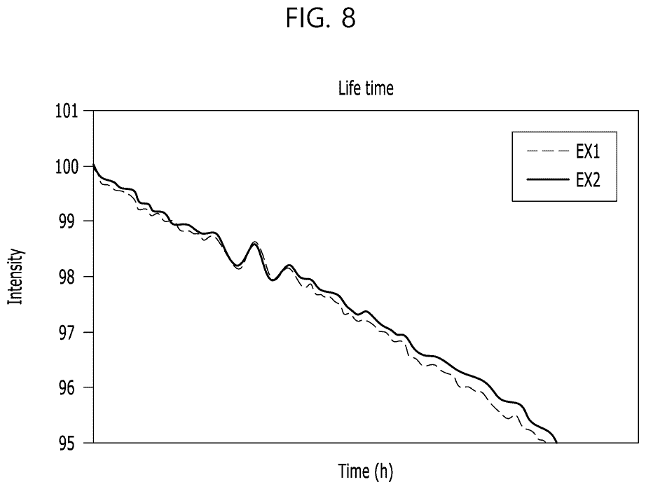

FIG. 6 is a graph showing spectra of light emitting devices of the first and second examples. FIG. 7 is a graph showing normalized spectra of the light emitting devices of the first and second examples. FIG. 8 is a graph showing lifespan of the light emitting devices of the first and second examples.

TABLE 1

| | Operating | Operating | Luminance | | | | |
|---|---|---|---|---|---|---|---|
| | voltage [V] @ | voltage | (Cd/A) | EQE | | | Lifespan |
| Classification | 10 mA/cm² | [V]@100 mA/cm² | (%) | (%) | CIEx | CIEy | (%) |
| EX1 | 0 | 0 | 100 | 100 | 0 | 0 | 100 |
| EX2 | +0.1 | −0.1 | 111 | 108 | −0.014 | 0.011 | 100 |

The light emitting device of the first example EX1 includes a single electron injection layer made of LiF as an electron injection unit EILU in the configuration of FIG. 1. The thickness of the electron injection layer in the first example EX1 was 20 Å.

The light emitting device of the second example EX2 is configured to include a first n-type layer 250, a p-type layer 260, and a second n-type layer 270, as shown in FIG. 1. In the second example EX2, the first n-type layer 250 was made of LiF, and each of the p-type layer 260 and the second n-type layer 270 was composed of a host and a dopant having energy band gap characteristics of FIG. 2. In the second example EX2, the thickness of the first n-type layer 250 was 20 Å, the thickness of the p-type layer 260 was 30 Å, and the thickness of the second n-type layer 270 was 50 Å.

Table 1 shows results of the second example EX2 compared to the first example EX1. Specifically, compared to the operating voltage values at current densities of 10 mA/cm² and 100 mA/cm² in the first example EX1, a change in the operating voltage value at each current density of the second example EX2 is represented. In addition, luminance, external quantum efficiency, and lifespan are set to 100% in the first example EX1, and in comparison therewith, external quantum efficiency and lifespan of the second example EX2 are represented. In some aspects, CIEx and CIEy are color coordinate system values and identify movement in the x- and y-axis directions between the first example EX1 and the second example EX2.

As shown in Table 1, the first and second examples EX1, EX2 exhibited similar operating voltage results, although there was a slight difference depending on the current density of 10 mA/cm² and 100 mA/cm².

Referring to Table 1 and FIG. 6, the second example EX2 exhibited an improvement in luminance of 111% compared to the first example EX1.

As shown in normalized spectra of FIG. 7, the main peak in the second example EX2 using the electron injection unit having an npn multilayer structure like the light emitting device according to an aspect of the present disclosure was the same as that in the first example EX1, but the half width in the long-wavelength region was decreased, demonstrating an improved electro-optical effect of pure green.

In addition, the second example EX2 showed a decrease in CIEx and an increase in CIEy compared to the first example EX1, indicating an improvement in color purity.

The first and second examples EX1, EX2 exhibited similar or the same lifespan characteristics as shown in Table 1 and FIG. 8.

Thus, in the second example EX2 according to an aspect of the present disclosure, the operating voltage was not increased and an equivalent lifespan and improved color purity and luminance were exhibited as compared to the first example EX1 having a single electron injection layer.

The results of second example EX2 indicate the significance of additional arrangement of the p-type layer 260 and the second n-type layer 270 of a pn junction in addition to the first n-type layer 250.

Moreover, the second example EX2 was configured such that the p-type layer 260 and the second n-type layer 270 were further provided and compared to the first example EX1, and thus the thickness of the electron injection unit (layer) was increased at the interface in contact with the second electrode CAT 300. However, as shown in FIG. 7, the main peak characteristics of the light emitting device were the same as those of the first example EX1 and the half width in the long-wavelength region was decreased, demonstrating an improvement in electro-optical efficiency.

### Second Experiment

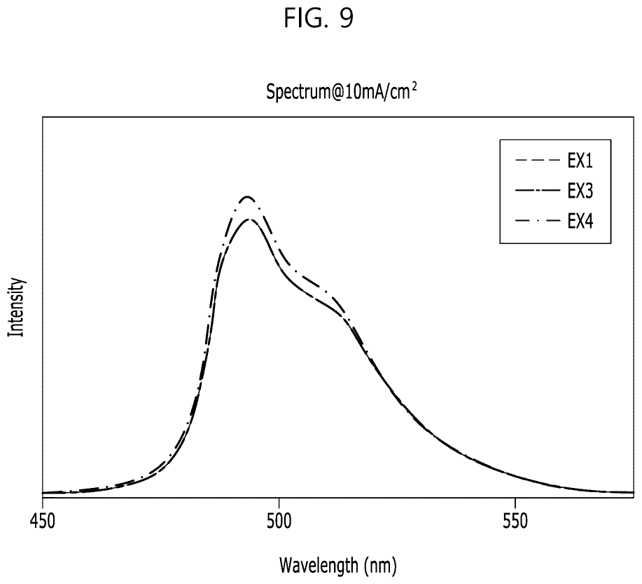

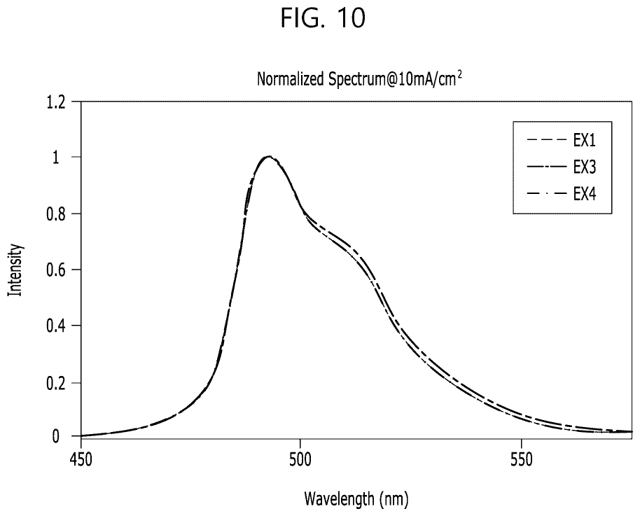

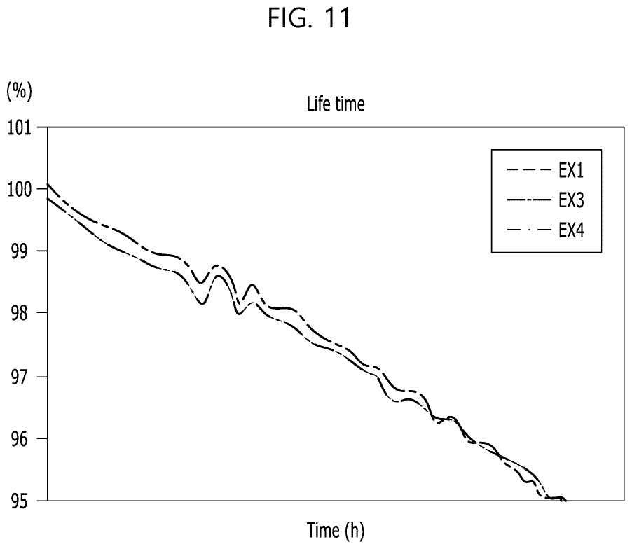

FIG. 9 is a graph showing spectra of light emitting devices of the first, third, and fourth examples. FIG. 10 is a graph showing normalized spectra of the light emitting devices of the first, third, and fourth examples. FIG. 11 is a graph showing lifespan of the light emitting devices of the first, third, and fourth examples.

TABLE 2

| | Operating | Operating | Luminance | | | | |
|---|---|---|---|---|---|---|---|
| | voltage | voltage | (Cd/A) | EQE | | | Lifespan |
| Classification | [V]@10 mA/cm² | [V]@100 mA/cm² | (%) | (%) | CIEx | CIEy | (%) |
| EX1 | 0 | 0 | 100 | 100 | 0 | 0 | 100 |
| EX3 | +1.6 | +1.7 | 98 | 98 | 0.006 | −0.004 | 100 |
| EX4 | +1.7 | +2.1 | 107 | 105 | −0.007 | 0.006 | 100 |

The light emitting device of the first example EX1 has the same configuration as in the first example. Specifically, the light emitting device of the first example EX1 includes a single electron injection layer including LiF as an electron injection unit EILU, as shown in FIG. 1. The thickness of the electron injection layer in the first example EX1 was 20 Å.

The light emitting device of the third example EX3 is configured such that an n-type charge generation layer n-CGL, a p-type charge generation layer p-CGL, a hole transport layer HTL, an emission layer EML, an electron transport layer ETL, an electron injection layer EIL, and a second electrode CAT are sequentially formed on the first electrode AND. Compared to the first example EX1, the third example EX3 includes an n-type charge generation layer and a p-type charge generation layer provided between the first electrode and the hole transport layer, and the remaining configuration is the same as in the first example EX1.

The light emitting device of the fourth example EX4 is configured such that an n-type charge generation layer n-CGL, a p-type charge generation layer p-CGL, a hole transport layer HTL, an emission layer EML, an electron transport layer ETL, an electron injection unit EILU (NL1, PL, NL2), and a second electrode CAT are sequentially formed on the first electrode AND. The configuration of the electron injection unit EILU is the same as in the second example EX2 described above.

The third and fourth examples EX3, EX4 each have an np junction adjacent to the first electrode AND, and show the effect when providing an np junction on the first electrode AND functioning as an anode.

In the third and fourth examples EX3, EX4, the p-type charge generation layer p-CGL and the n-type charge generation layer n-CGL have properties of the p-type layer PL and the second n-type layer NL2 described in FIG. 2, respectively. Specifically, the p-type charge generation layer p-CGL is composed of a p-type host and a p-type dopant, and the n-type charge generation layer is composed of an n-type host doped with lithium ions.

As shown in Table 2 and FIG. 11, lifespan characteristics were equivalent in the first example EX1, the third example EX3, and the fourth example EX4. As shown in Table 2 and FIGS. 9 and 10, the fourth example EX4 improves an improvement in luminance and external quantum efficiency as compared to the first and third examples EX1, EX3. For example, the electron injection efficiency is improved in the fourth example EX4 when a pn junction is adjacent to the second electrode CAT, as shown in the fourth example EX4, thereby enabling the formation of abundant excitons in the emission layer.

However, in the third and fourth examples EX3, EX4, regardless of injection of holes from the first electrode AND, band bending occurs near the LUMO energy level in the n-type charge generation layer adjacent to the first electrode AND. In this case, the n-type charge generation layer reduces hole injection efficiency, which tends to greatly increase operating voltage. The increase in operating voltage becomes more severe with an increase in the operating current.

For example, the common result of Tables 1 and 2 showed that, when the electron injection unit includes an npn multilayer structure and is adjacent to the second electrode CAT, luminous efficacy of the emission layer may be increased by improving the electron injection efficiency. When comparing Table 1 and Table 2, adding an np junction structure adjacent to the first electrode AND lowers the hole injection efficiency and increases operating voltage.

In this case, the light emitting device according to an aspect of the present disclosure may be configured such that the electron injection unit including the first n-type layer, the p-type layer, and the second n-type layer (e.g., an npn structure) is provided between the electron transport layer and the second electrode, as shown in FIGS. 1 and 2 and the second example EX2.

The significance of alternate arrangement of different types of layers in the multilayer configuration of the electron injection unit will be examined below.

### Third Experiment

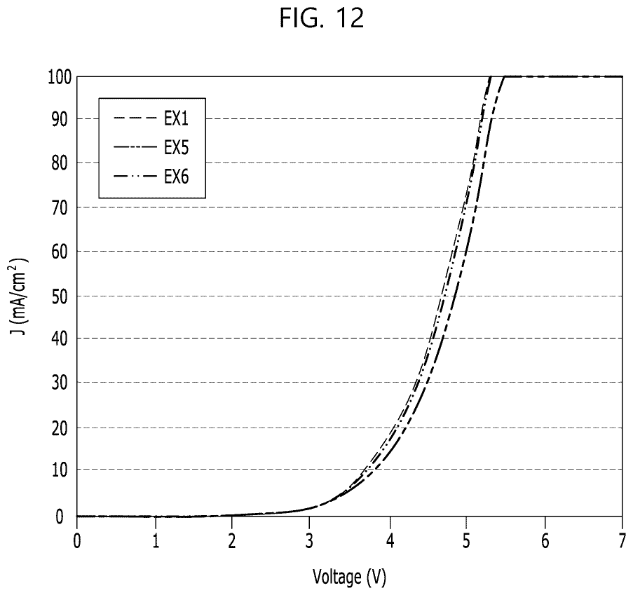

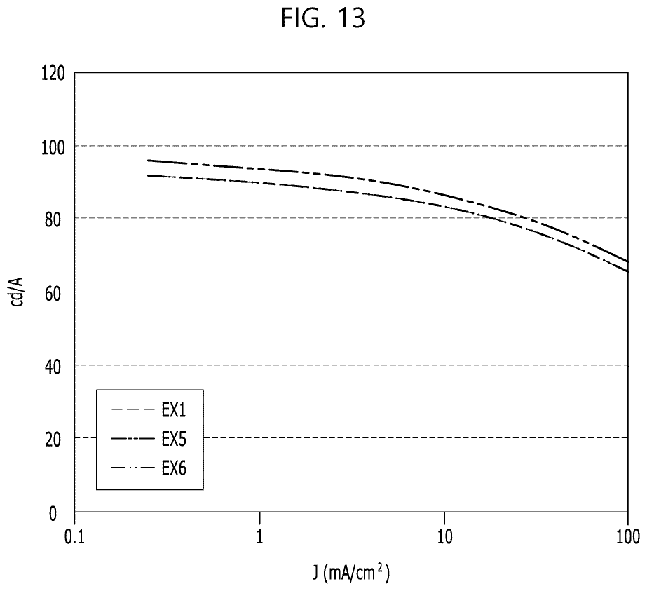

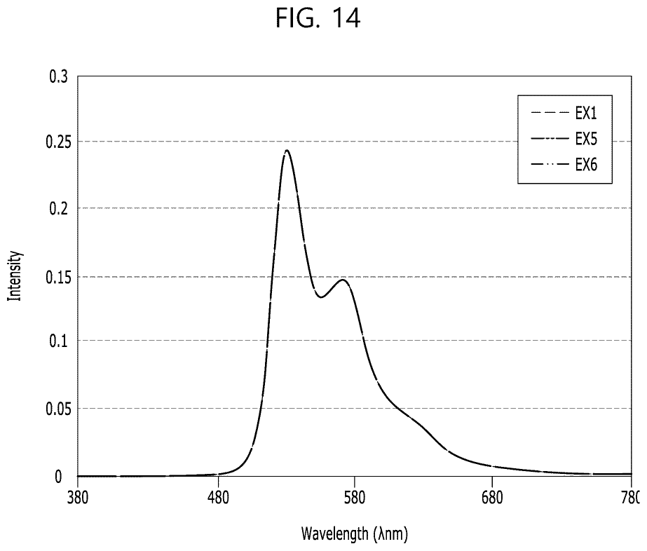

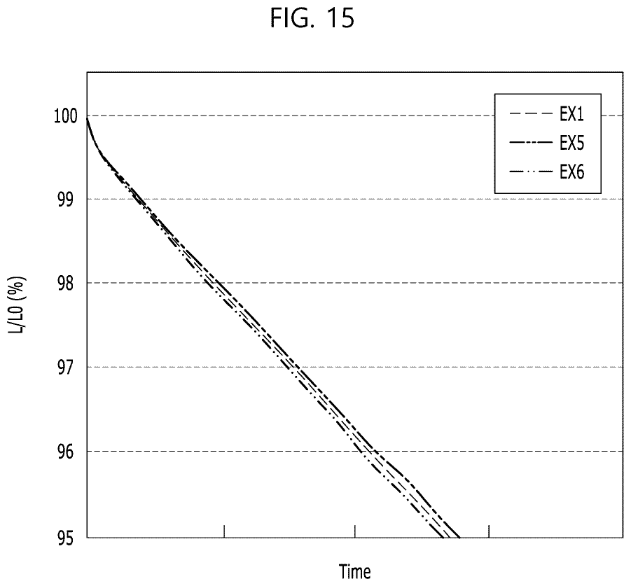

FIG. 12 is a graph showing current density (J-V) characteristics of light emitting devices of the first, fifth, and sixth examples. FIG. 13 is a graph showing the relationship between current density and luminance of the light emitting devices of the first, fifth, and sixth examples. FIG. 14 is a graph showing spectra of the light emitting devices of the first, fifth, and sixth examples. FIG. 15 is a graph showing lifespan of the light emitting devices of the first, fifth, and sixth examples.

TABLE 3

| | Operating | Operating | Luminance | | | | |
|---|---|---|---|---|---|---|---|
| | voltage | voltage | (Cd/A) | EQE | | | Lifespan |
| Classification | [%]@10 mA/cm² | [%]@100 mA/cm² | (%) | (%) | CIEx | CIEy | (%) |
| EX1 | 100 | 100 | 100 | 100 | 0 | 0 | 100 |
| EX5 | 100 | 101 | 100 | 100 | 0 | 0 | 100 |
| EX6 | 100 | 100 | 100 | 100 | 0.001 | −0.001 | 100 |

The light emitting device of the first example EX1 has the same configuration as in the first experiment. Specifically, the light emitting device of the first example EX1 includes a single electron injection layer EIL made of LiF as an electron injection unit EILU in the configuration of FIG. 1. The thickness of the electron injection layer in the first example EX1 was 20 Å.

Compared to the first example EX1, the light emitting device of the fifth example EX5 is formed by sequentially stacking an n-type charge generation layer nCGL and an electron injection layer EIL.

Compared to the first example EX1, the light emitting device of the sixth example EX6 is formed by sequentially stacking an electron injection layer EIL and an n-type charge generation layer nCGL. The sixth example EX6 has the opposite configuration of the n-type charge generation layer nCGL and the electron injection layer EIL to that of the fifth example EX5.

In the fifth and sixth examples EX5, EX6, the p-type charge generation layer p-CGL and the n-type charge generation layer n-CGL have properties of the p-type layer PL and the second n-type layer NL2 described in FIG. 2, respectively. Specifically, the p-type charge generation layer p-CGL is composed of a p-type host and a p-type dopant, and the n-type charge generation layer is composed of an n-type host doped with lithium ions.

Referring to FIGS. 12 to 14 and Table 3, the examples EX1, EX5, EX6 exhibited almost equivalent levels of operating voltage, luminance, external quantum efficiency, color purity, and lifespan characteristics.

FIGS. 12 to 14 and Table 3 demonstrate that there is no improvement when a plurality of n-type layers or n-type charge generation layers with the same or similar characteristics are provided adjacent to the second electrode CAT 300.

The significance of the configuration of the second n-type layer including a single n-type host and an n-type dopant is discussed the fourth experiment.

### Fourth Experiment

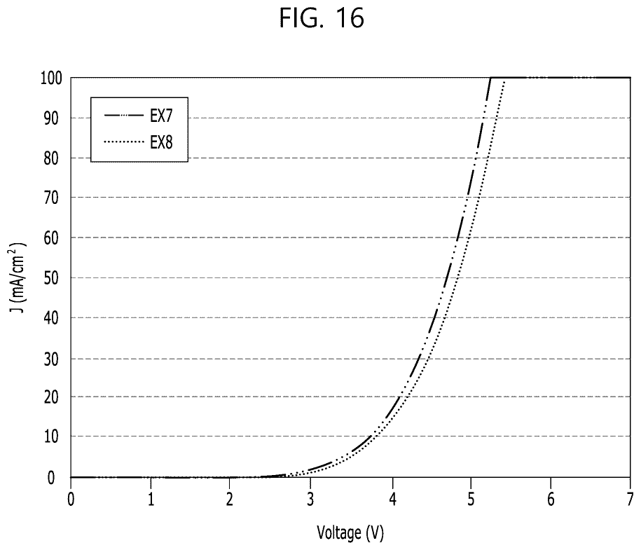

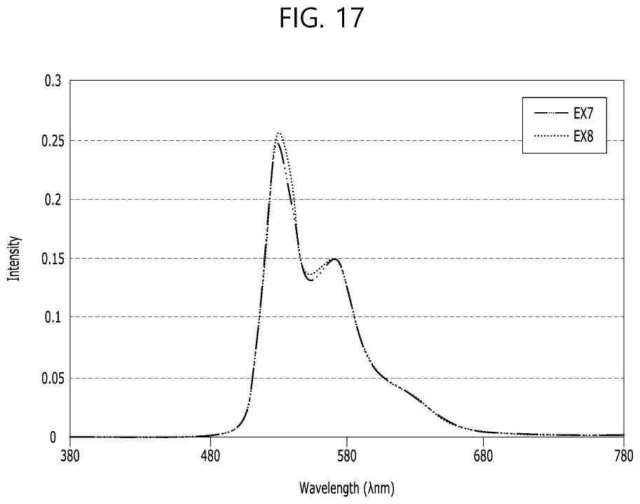

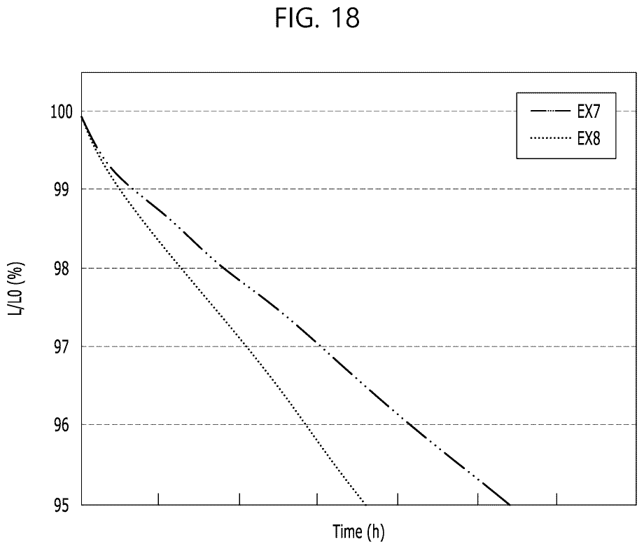

FIG. 16 is a graph showing current density characteristics of light emitting devices of the seventh and eighth examples. FIG. 17 is a graph showing spectra of the light emitting devices of the seventh and eighth examples. FIG. 18 is a graph showing lifespan of the light emitting devices of the seventh and eighth examples.

TABLE 4

| | Operating | Operating | Luminance | | | | |
|---|---|---|---|---|---|---|---|
| | voltage | voltage | (Cd/A) | EQE | | | Lifespan |
| Classification | [V]@10 mA/cm² | [V]@100 mA/cm² | (%) | (%) | CIEx | CIEy | (%) |
| EX7 | 0 | 0 | 100 | 100 | 0 | 0 | 100 |
| EX8 | +0.02 | +0.16 | 104 | 104 | −0.002 | +0.002 | 67 |

The seventh example EX7 has the same configuration as in the first example EX1, with the exception that the electron injection layer is configured such that the n-type organic host is doped with lithium ions, which is illustrated in the second n-type layer NL2 of FIG. 2. Specifically, the light emitting device of the seventh example EX7 is configured such that a hole injection layer HIL, a hole transport layer HTL, an emission layer EML, an electron transport layer ETL, an electron injection layer EIL made mainly of an organic material (n-organic host +nd), and a second electrode CAT are sequentially formed on the first electrode AND.

The eighth example EX8 is configured such that the electron injection layer is made of an n-type organic host alone in an undoped state, differing from the electron injection layer made mainly of the organic material as in the seventh example EX7.

The remaining configuration of the eighth example EX8 except for the electron injection layer is the same as that of the seventh example EX7.

The seventh example EX7 and the eighth example EX8 through Table 4 and FIGS. 16 to 18 illustrate that, when the electron injection layer of the eighth example EX8 was made mainly of the organic material and did not include the metal dopant nd, the operating voltage increased and lifespan dramatically decreased.

Referring back to the third experiment, the first example including the single EIL and the fifth and sixth examples EX5, EX6, which each include the n-type layer with an n-type organic host and a metal dopant (EIL/NL or NL/EIL), exhibited almost equivalent levels of lifespan, operating voltage, efficiency, luminance, and color purity.

The fourth experiment demonstrates that the single electron injection layer made mainly of an n-type organic material exhibited at least a certain level of efficiency without deteriorating lifespan characteristics only when including a metal dopant.

The light emitting device of the seventh example EX7, which includes the electron injection layer mainly made of an organic material and includes a metal dopant, and the light emitting device of the first example EX1, which includes an electron injection layer is made of an inorganic compound alone, exhibited equivalent operating voltage, luminance, efficiency, color purity, and lifespan characteristics.

Through the first to fourth experiments, when the electron injection unit including the first n-type layer, the p-type layer, and the second n-type layer is provided between the electron transport layer and the second electrode as in the second example EX2, luminance, external quantum efficiency, and color purity may be greatly improved without a decrease in operating voltage and lifespan, demonstrating the significance of the electron injection unit.

Meanwhile, the light emitting device described above may be provided for each sub-pixel of a substrate to perform display. A light emitting display device according to an aspect of the present disclosure is described below.

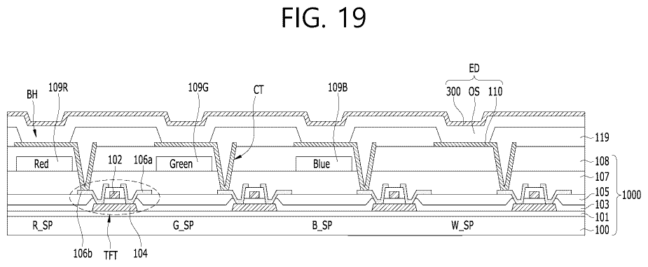

FIG. 19 is a cross-sectional view showing the light emitting display device according to an aspect of the present disclosure.

As shown in FIG. 19, the light emitting display device according to an aspect of the present disclosure may be commonly applied to a plurality of sub-pixels R_SP, G_SP, B_SP, W_SP, emitting white light through the first electrode 110 at the emission side.

As shown in FIG. 19, the light emitting display device according to an aspect of the present disclosure includes a substrate 100 having a plurality of sub-pixels R_SP, G_SP, B_SP, W_SP, a light emitting device ED commonly provided on the substrate 100, a thin film transistor TFT provided in each of the sub-pixels R_SP, G_SP, B_SP, W_SP and connected to the first electrode 110 of the light emitting device ED, and color filter layers 109R, 109G, 109B provided under the first electrode 110 of at least one of the sub-pixels.

FIG. 19 shows the light emitting display device including the white sub-pixel W_SP, but the present disclosure is not limited thereto, and the configuration in which the white sub-pixel W_SP is omitted and only the red, green, and blue sub-pixels R_SP, G_SP, B_SP are provided is also possible. In some cases, a combination of a cyan sub-pixel, a magenta sub-pixel, and a yellow sub-pixel capable of representing white, in place of the red, green and blue sub-pixels, is also possible.

The thin film transistor TFT includes, for example, a gate electrode 102, a semiconductor layer 104, and a source electrode 106a and a drain electrode 106b connected to both sides of the semiconductor layer 104. Additionally, a channel passivation layer may be further provided on the semiconductor layer 104 in which the channel is located, to prevent direct connection between the source/drain electrodes 106a, 106b and the semiconductor layer 104. A buffer layer 101 may be provided on the substrate 100, and the thin film transistor TFT may be disposed on the buffer layer 101.

A gate insulating film 103 is provided between the gate electrode 102 and the semiconductor layer 104.

The semiconductor layer 104 may be formed of, for example, any one or a combination of two or more selected from among an oxide semiconductor, amorphous silicon, and polycrystalline silicon. For example, when the semiconductor layer 104 is an oxide semiconductor, the heating temperature required to form a thin film transistor may be lowered, and thus the substrate 100 has a high degree of freedom in use, so application to a flexible display device may become advantageous.

The gate electrode 102 may be provided on the gate insulating film 103, and an interlayer insulating film 105 may be further provided between the gate electrode 102 and the source electrode 106a/drain electrode 106b.

Moreover, the drain electrode 106b of the thin film transistor TFT may be connected to the first electrode 110 in the region of a contact hole CT provided in first passivation films 107 and the second passivation film 108.

The first passivation film 107 is provided primarily to protect the thin film transistor TFT, and color filters 109R, 109G, 109B may be provided on the first passivation film 107.

The second passivation film 108 may be provided on the first passivation film 107 including the color filters 109R, 109G, 109B.

As shown in FIG. 19, when the sub-pixels include a red sub-pixel R_SP, a green sub-pixel G_SP, a blue sub-pixel B_SP, and a white sub-pixel W_SP, first to third color filters 109R, 109G, 109B may be provided to the sub-pixels R_SP, G_SP, B_SP, respectively, other than the white sub-pixel W_SP, allowing white light emitted through the first electrode 110 to pass at each wavelength. The second passivation film 108 is configured to cover the first to third color filters 109R, 109G, 109B and formed under the first electrode 110. The first electrode 110 is formed on the surface of the second passivation film 108 excluding the contact hole CT and is connected to either the drain electrode 106b or the source electrode 106a of the thin film transistor TFT, receiving an electrical signal by the thin film transistor TFT.

Here, a structure including the substrate 100, the thin film transistor TFT, the color filters 109R, 109G, 109B, and the first passivation films 107 and the second passivation film 108 may be referred to as a thin film transistor array substrate 1000.

The light emitting device ED is formed on the thin film transistor array substrate 1000 including a bank 119 defining a light emitting portion BH. The light emitting device ED may include a transparent first electrode 110 and a reflective second electrode 300 facing the same, and may sequentially include a hole injection layer HIL, a hole transport layer HTL, an emission layer EML, an electron transport layer ETL, and an electron injection unit EILU, as described above, between the first electrode 110 and the second electrode 300. The electron injection unit EILU in contact with the second electrode 300 is included in a form in which layers with different polarities, such as a first n-type layer, a p-type layer, and a second n-type layer, are alternately arranged, thus improving electron injection efficiency and luminous efficacy in the emission layer. Moreover, the p-type layer activates electron generation of the adjacent first and second n-type layers and enables electron transfer by a tunneling effect, so operating voltage is not increased or charges do not accumulate, and thus problems such as shortened lifespan do not occur.

The first electrode 110 may be provided dividedly for each sub-pixel, and the remaining layers except for the first electrode 110 of the light emitting device ED may be provided integrally throughout the active area without separate division for each sub-pixel. For example, a structure having multiple stacks of FIGS. 3 to 5 between the first electrode 110 and the second electrode 300 may be used, in lieu of the light emitting device of FIG. 1. As such, the electron injection unit EILU adjacent to the second electrode 300 may be configured such that the layers with different polarities described above are alternately arranged, thus improving electron injection efficiency and luminous efficacy in the emission layer.

Either the first electrode 110 or the second electrode 300 may be connected to the thin film transistor TFT.

The light emitting display device of FIG. 19 described above is illustrated as implementing bottom emission, but the present disclosure is not limited thereto. For example, the first electrode 110 may be a reflective electrode, the second electrode 300 may be a transparent electrode or a semi-transparent electrode, and the color filters may be located above the second electrode 300, thereby realizing a top-emission light emitting display device.

In the light emitting display device according to an aspect of the present disclosure, the electron injection unit in contact with the second electrode (cathode) has an npn structure in which layers with different polarities are alternately arranged to increase the electron injection characteristics and the amount of electrons injected.

In the light emitting display device according to an aspect of the present disclosure, when the electron injection unit has a thicker configuration than the single electron injection layer, electrons may pass by a tunneling effect without any barrier by the energy band gap of the organic material of the p-type layer of different polarity, improving the device efficiency without increasing operating voltage.

In the light emitting display device according to an aspect of the present disclosure, the p-type layer of the electron injection unit induces the first and second n-type layers of opposite polarity to generate electrons, increasing the amount of electrons transferred to the emission layer and increasing the amount of excitons in the emission layer, which may contribute to improving device efficiency.

In the light emitting display device according to an aspect of the present disclosure, in a configuration in which layers with different polarities are stacked, the first and second n-type layers allow electrons to move through the LUMO energy level or work function of the same or similar characteristics, and the p-type layer allows electrons to pass therethrough by a tunneling effect and to move efficiently to the electron transport layer.

In the light emitting display device according to an aspect of the present disclosure, electron injection efficiency may be increased and the amount of electrons may be increased depending on the energy band gap of the constituent materials in the electron injection unit and the work function of the dopant and the main material, thereby improving luminous efficacy and color purity efficiency.

In the light emitting display device according to an aspect of the present disclosure, the efficiency in the emission layer may increase the amount of electrons injected to the emission layer via the electron injection unit and the electron transport layer, and emission characteristics and performance of the light emitting device may be improved without increasing voltage or reducing lifespan during this process.

In the light emitting display device according to an aspect of the present disclosure, the total thickness of the electron injection unit having an npn structure may be set to a thickness that enables reproducibility and electron tunneling. When a voltage is applied to the second electrode (e.g., a cathode), the p-type and n-type layers with different polarities may generate charges that may be transferred to the emission layer via the electron injection unit and the electron transport layer by a tunneling effect. The changes in the emission layer increases the generation of excitons in the emission layer, which may contribute to improving efficiency.

In the light emitting device and the light emitting display device according to aspects of the present disclosure, the electron injection unit in contact with the second electrode (cathode) may have an npn structure in which layers with different polarities are alternately arranged, thus increasing the electron injection characteristics and the amount of electrons injected. Therefore, efficiency in the emission layer may be increase the amount of electrons injected to the emission layer via the electron injection unit and the electron transport layer, and emission characteristics and performance of the light emitting device may be improved without increasing the voltage or reducing the lifespan during this process.

In addition, the total thickness of the electron injection unit having an npn structure may fall in the range of 60 Å to 140 Å, and thus, when a voltage is applied to the second electrode (cathode), the first and second n-type layers allow electrons to move through the LUMO energy level or work function of the same or similar characteristics, and the p-type layer allows electrons to pass therethrough by a tunneling effect.

The p-type layer of the electron injection unit induces the first and second n-type layers of opposite polarity to generate electrons, thereby increasing the amount of electrons transferred to the emission layer and thus increasing the amount of excitons in the emission layer, which may contribute to improving device efficiency.

In comparison with the structures of the aspects of the present disclosure, as demonstrated, stacking a plurality of n-type layers as the electron injection layer or electron injection unit has little difference in efficiency from the structure having a single electron injection layer.

In addition, the light emitting device and the light emitting display device according to the aspects of the present disclosure demonstrates that the main peak is the same and the half width in the long-wavelength region is decreased under the condition that the overall thickness of the light emitting device is increased based on normalized spectrum results. With the provision of the electron injection unit having a multilayer structure, optical efficiency is not improved by a cavity effect due to an increase in the overall thickness of the light emitting device, but an electrical effect is obtained due to use of the electron injection unit.

There is a constant need to improve the efficiency of light emitting devices for high-luminance products, but changing the structure or material may cause side effects such as increased operating voltage and shortened lifespan.

In the light emitting device and the light emitting display device according to the aspects of the present disclosure, the p-type layer of the electron injection unit induces the first and second n-type layers of opposite polarity to generate electrons, thereby increasing the amount of electrons transferred to the emission layer and increases the amount of excitons in the emission layer, which may contribute to improving device efficiency.

A light emitting device according to one aspect of the present disclosure may comprise a first electrode and a second electrode facing each other. At least one stack is provided between the first electrode and the second electrode and the stack comprises a hole transport layer, an emission layer, and an electron transport layer and an electron injection unit. The electron injection unit may comprise a first n-type layer, a p-type layer, and a second n-type layer.

In a light emitting device according to one aspect of the present disclosure, the first n-type layer may comprise an n-type inorganic material and the second n-type layer comprises an n-type organic host and an n-type dopant.

In a light emitting device according to one aspect of the present disclosure, the n-type organic host may comprise a phenanthroline-based compound.

In a light emitting device according to one aspect of the present disclosure, the n-type dopant may comprise an alkali metal.

In a light emitting device according to one aspect of the present disclosure, the p-type layer may comprise a p-type organic material.

In a light emitting device according to one aspect of the present disclosure, the p-type layer may comprise a p-type organic host and a p-type dopant.

In a light emitting device according to one aspect of the present disclosure, the first n-type layer may be in contact with the electron transport layer of an adjacent stack, the second n-type layer may be in contact with the second electrode, and the p-type layer may be in contact with the first n-type layer and the second n-type layer at both sides.

In a light emitting device according to one aspect of the present disclosure, the first n-type layer may be thinnest in the electron injection unit.

In a light emitting device according to one aspect of the present disclosure, a total thickness of the electron injection unit may be 60 Å to 140 Å.

In a light emitting device according to one aspect of the present disclosure, multiple stacks may be provided between the first electrode and the second electrode, and emission layers in the multiple stacks may emit light of same color.

In a light emitting device according to one aspect of the present disclosure, wherein multiple stacks may be provided between the first electrode and the second electrode, and emission layers in the multiple stacks may emit light of different colors.

A light emitting display device according to one aspect of the present disclosure may a substrate comprising a plurality of sub-pixels, a thin film transistor provided in each of the plurality of sub-pixels, a light emitting device as mentioned as the above. At least one of the plurality of sub-pixels may comprise the light emitting device and a first electrode of the light emitting device is connected to the thin film transistor.

As is apparent from the above description, a light emitting device and a light emitting display device according to aspects of the present disclosure have the following effects.

An electron injection unit in contact with the second electrode (cathode) has an npn structure in which layers with different polarities are alternately arranged, so that not only electron injection characteristics but also the amount of electrons injected may be increased.

Even when the electron injection unit has a thicker configuration than a single electron injection layer, electrons may pass by a tunneling effect without any barrier by the energy band gap of the organic material of the p-type layer of different polarity, resulting in improved device efficiency without increasing operating voltage.

The p-type layer of the electron injection unit induces the first and second n-type layers of opposite polarity to generate electrons, thereby increasing the amount of electrons ultimately transferred to the emission layer and thus increasing the amount of excitons in the emission layer, which may contribute to improving device efficiency.

In a configuration in which layers with different polarities are stacked, the first and second n-type layers allow electrons to move through the LUMO energy level or work function of the same or similar characteristics, and the p-type layer allows electron to pass therethrough by a tunneling effect and to move efficiently to the electron transport layer via the electron injection unit from the second electrode.

Depending on the energy band gap of the constituent materials in the electron injection unit and the work function of the dopant and the main material, electron injection efficiency may be increased and the amount of electrons may be increased, thereby improving luminous efficacy and color purity efficiency.

The efficiency in the emission layer may be increase the amount of electrons injected to the emission layer via the electron injection unit and the electron transport layer, and emission characteristics and performance of the light emitting device may be improved without increasing voltage or reducing lifespan during this process.

The total thickness of the electron injection unit having an npn structure is set to a thickness that enables reproducibility and electron tunneling. When a voltage is applied to the second electrode (cathode), the p-type and n-type layers with different polarities generate charges, and the generated charges are transferred to the emission layer via the electron injection unit and the electron transport layer by a tunneling effect, increasing the generation of excitons in the emission layer, which may contribute to improving efficiency.

While the aspects of the present disclosure have been described with reference to the accompanying drawings, the present disclosure is not limited to the aspects and may be embodied in various different forms, and those skilled in the art will appreciate that the present disclosure may be embodied in specific forms other than those set forth herein without departing from the technical idea and essential characteristics of the present disclosure. The disclosed embodiments are therefore to be construed in all aspects as illustrative and not restrictive.

What is claimed is:

1. A light emitting device, comprising:
a first electrode and a second electrode facing each other;
at least one stack of layers between the first electrode and the second electrode and comprising a hole transport layer, an emission layer, and an electron transport layer; and
an electron injection unit between the at least one stack and the second electrode,
wherein the electron injection unit comprises a first n-type layer, a p-type layer, and a second n-type layer.

2. The light emitting device according to claim 1, wherein the first n-type layer comprises an n-type inorganic material and the second n-type layer comprises an n-type organic host and an n-type dopant.

3. The light emitting device according to claim 2, wherein the n-type organic host comprises a phenanthroline-based compound.

4. The light emitting device according to claim 2, wherein the n-type dopant comprises an alkali metal.

5. The light emitting device according to claim 2, wherein the p-type layer comprises a p-type organic material.

6. The light emitting device according to claim 2, wherein the p-type layer comprises a p-type organic host and a p-type dopant.

7. The light emitting device according to claim 1, wherein the first n-type layer contacts the electron transport layer of an adjacent stack of layers, the second n-type layer contacts the second electrode, and the p-type layer contacts the first n-type layer and the second n-type layer at both sides.

8. The light emitting device according to claim 1, wherein the first n-type layer has a thickness less than the second n-type layer and the p-type layer.

9. The light emitting device according to claim 1, wherein a total thickness of the electron injection unit is 60 Å to 140 Å.

10. The light emitting device according to claim 1, wherein the at least one stack includes a plurality of stacks provided between the first electrode and the second electrode, and each emission layer in a corresponding stack emits light of same color.

11. The light emitting device according to claim 1, wherein multiple stacks are provided between the first electrode and the second electrode, and emission layers in the multiple stacks emit light of different colors.

12. A light emitting display device, comprising:
a substrate comprising a plurality of sub-pixels; and
a thin film transistor provided in each of the plurality of sub-pixels,
wherein at least one sub-pixel of the plurality of sub-pixels comprises a light emitting device comprising:
a first electrode and a second electrode facing each other, wherein the first electrode is connected to the thin film transistor;
at least one stack provided between the first electrode and the second electrode and comprising a hole transport layer, an emission layer, and an electron transport layer; and
an electron injection unit between the at least one stack and the second electrode and including a first n-type layer, a p-type layer, and a second n-type layer.

13. The light emitting display device of claim 12, wherein the first electrode is associated with a single subpixel, and the second electrode is disposed over each sub-pixel of the plurality of sub-pixels.

14. The light emitting display device of claim 12, wherein the second electrode comprises a reflective material, and the first electrode comprises a transparent material.

15. The light emitting display device of claim 12, wherein the electron injection unit contacts a bottom surface of the second electrode and a top surface of the electron injection unit.

16. The light emitting display device of claim 12, wherein the at least one stack comprises a first emission layer corresponding to a color of the at least one sub-pixel and a second emission layer corresponding to the color.

17. The light emitting display device of claim 16, wherein the first emission layer is disposed between a first common layer and a second common layer, and wherein the second emission layer is disposed between a third common layer and a fourth common layer.

18. The light emitting display device of claim 17, wherein the first common layer and the third common layer include at least one of a hole injection layer, a hole transport layer, and an electron blocking layer, and
wherein the second common layer and the fourth common layer may include at least one of a hole blocking layer, an electron transport layer, and an electron injection layer.

19. The light emitting display device of claim 12, wherein the at least one stack comprises a first blue emission layer and a second blue emission layer.

20. The light emitting display device of claim 19, wherein at least one charge generation layer and a phosphorescent emission layer are disposed between the first blue emission layer and the second blue emission layer.
